(19) United States
(12) Patent Application Publication
(10) Pub. No.: US 2009/0274974 A1
(43) Pub. Date: Nov. 5, 2009

(54) SPIN-ON GRADED K SILICON ANTIREFLECTIVE COATING

(76) Inventors: David Abdallah, Bernardsville, NJ (US); Ralph R. Dammel, Flemington, NJ (US)

Correspondence Address: ALAN P. KASS;AZ ELECTRONIC MATERIALS USA CORP., 70 MEISTER AVENUE, SOMERVILLE, NJ, 08876, US

(21) Appl. No.: 12/112,221

(22) Filed: Apr. 30, 2008

(51) Int. Cl. G03F 7/004; B05D 5/06; G03F 9/00

(52) U.S. Cl. 430/270.1; 427/162; 430/449

(57) ABSTRACT

Graded absorption silicon based antireflective coating compositions are described.

The present invention is related to graded absorption silicon based antireflective coatings.

The extension of 193 nm optical lithography to numerical aperture (NA) values above 1.0 provides a means of achieving increased resolution for a printable minimum feature size, and therefore allows for further scaling of integrated circuits (IC) by the semiconductor industry.

Current state-of-the-art techniques in optical projection printing (such as 193 nm immersion lithography at NA=1.2) can resolve features beyond 50 nm half-pitch in photoresists with good linewidth control when planar, low reflectivity substrates are used. However, when photoresists are exposed on reflective substrates in the presence of underlying surface topography, critical dimension (CD) control problems are exacerbated under high NA imaging conditions, and lead to the deterioration of the quality of the printed image.

Reflection of light from the substrate/resist interface produces variations in the light intensity and scattering in the resist during exposure, resulting in non-uniform photoresist linewidth upon development. Light can scatter from the interface into regions of the resist where exposure was not intended, resulting in linewidth variations. The amount of scattering and reflection will typically vary from region to region resulting in linewidth non-uniformity. The interface between the resist and substrate can be highly reflective causing standing waves and contribute to dose fluctuations with resist film thickness variations throught thin film interference effects.

Linewidth control problems due to non-uniform reflectance also arise from substrate topography. Any image on the wafer will cause impinging light to scatter or reflect in various uncontrolled directions (reflective notching), affecting the uniformity of resist development. As the topography becomes more complex with efforts to design more complex circuits, the effects of reflected light become much more critical.

As a result of the optical effects at high NA and reflective notching described above, extending the resolution capability of 193 nm lithography requires reflectivity control over a wider range of angles.

A common method to address problems related to reflectivity control within imaging layers is to apply a bottom antireflective coating (BARC) formed beneath the photoresist layer is capable of eliminating both the swing and notching problems.

Two types of BARC layers are commonly used by the semiconductor industry. Spin-on BARCs are typically organic materials applied as a liquid formulation to the semiconductor substrate from a spin-coating station (track). After the BARC film is formed, a high temperature bake (post-apply bake) is used to remove the casting solvent and to crosslink the polymer components, so as to form a BARC layer that is impervious to the casting solvent used in the photoresist formulation that is coated subsequently. In this case, the optical properties are defined by the chemical functionality of the polymer components present in the formulation.

Alternatively, BARCs deposited through radiation assisted techniques such as chemical vapor deposition (CVD), high density plasma, sputtering, ion beam or electron beam can be organic (APF from Applied Materials, amorphous carbon U.S. Pat. No. 6,423,384), inorganic or hybrid materials (e.g. silicon nitrides, silicon oxynitrides, hydrogenated silicon carboxynitrides, or combinations thereof) that are applied from a gas phase in a stand-alone deposition chamber, utilizing precursors capable of being volatilized, combined with gaseous co-reactants and converted to their corresponding hybrid or inorganic derivatives at high temperatures or assisted by plasma conditions. In this case, the chemical nature of the precursors and the reactant concentration ratios define the net chemical composition and the optical properties of the deposited BARC layer.

In any case, as the NA exceeds 1.0, a homogeneous single layer bottom antireflective coating may not suffice in keeping substrate reflectivity below 1% at all incident angles, as indicated by Abdallah et al. (Proceedings of SPIE, Vol. 5753, p. 417, 25). One way to reduce the detrimental side effects of high-NA imaging and reflective notching when practicing high resolution lithography includes the use of discrete or continuous bottom antireflective multilayers with optical properties defined throughout the antireflective element(s) in such a way that the difference in optical indices across an interfaces are minimized to increase light penetration into each successive layer. The first interface, at bottom of the resist, is the most highly sensitive so closer agreement of the optical indices across this interface can lead to better reflectivity control. Considering that BARC films absorb light, subsequent interfaces will exhibit less sensitivity to differences in optical indices across an interface since the light intensity incident at these interfaces will be diminished. This idea has been accomplished by the use of either a multilayer BARC or a continuously graded BARC.

In the case of a multilayer BARC, two or more antireflective layers with distinct and properly selected refractive index (n) and absorption coefficient (k) are consecutively applied on the semiconductor substrate, thus forming an antireflective stack with enhanced optical properties with respect to a single layer BARC. The simplest case for a multilayer BARC, namely a dual-layer BARC, has been previously described as being effective at reducing unwanted reflectivity in semiconductor substrates by, for example, using combinations of all-organic (Abdallah et al., Proceedings of SPIE Vol. 5753, p. 417, 25). Trilayer processes are also examples of a dual layer BARC (Abdallah et al., J. Photopoolymer 2007, 20(5), 697-705) which are increasingly being integrated into more and more intergrated circuit levels where single layer processes are deemed inadequate for direct substrate etching.

Others have used plasma-enhanced enhanced chemical vapor deposition (CVD) to form continuously graded BARC films with n and k values that can be tuned and varied throughout the depth of the antireflective layer. However, CVD can be expensive and can cause reflective notching problems.

### SUMMARY OF THE INVENTION

A method is provided comprising (a) coating a substrate with an antireflective coating composition comprising a transparent siloxane, a light absorbing dye, and optionally, a curing agent; (b) heating the coated substrate at a temperature where a portion of the dye sublimes out of the antireflective coating composition to form a non-uniform absorption graded antireflective coating layer having a top surface and a bottom surface interfacing with the substrate, where the non-uniform absorption graded antireflective coating layer has an absorption coefficient (k) value of 0.0<k<0.1 at the top surface which increases smoothly and continuously to a value of 0.2>k>1 at the interface of the bottom surface and substrate. The transparent siloxane comprises a repeating unit having the formula

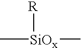

where R is unsubstituted or substituted alkyl, unsubstituted or substituted acyl, unsubstituted or substituted acyloxy, halogen, or hydroxyl; and x is 1.5.

The novel composition is useful for imaging photoresists which are coated over the novel antireflective coating composition and also for etching the substrate. The novel composition enables a good image transfer from the photoresist to the substrate, and also has good absorption characteristics to prevent reflective notching and line width variations or standing waves in the photoresist. Additionally, substantially no intermixing is present between the antireflective coating and the photoresist film. The antireflective coating also has good solution stability and forms thin films with good coating quality, the latter being particularly advantageous for lithography.

In addition, a non-uniform absorption graded antireflective coating layer having a top surface and a bottom surface interfacing a substrate, where the non-uniform absorption graded antireflective coating layer has an absorption coefficient (k) value of 0.0<k<0.1 at the top surface which increases smoothly and continuously to a value of 0.2>k>1 at the interface of the bottom surface and substrate is also provided.

In addition, a coated substrate comprising a substrate having thereon a non-uniform absorption graded antireflective coating layer formed from an antireflective coating composition and a coating layer of a photoresist over the non-uniform absorption graded antireflective coating layer, where the antireflective coating composition comprises a transparent siloxane and a light absorbing dye is also provided. In some instances, the substrate can be an organic antireflective coating layer, formed from an organic antireflective coating composition.

In addition, a coated substrate comprising a substrate having thereon an organic antireflective coating layer, formed from an organic antireflective coating composition, the antireflective coating layer having thereon a non-uniform absorption graded antireflective coating layer, formed by the method described herein from a transparent siloxane and a light absorbing dye, the non-uniform absorption graded antireflective coating layer having thereon a coating layer of a photoresist is also provided.

### DETAILED DESCRIPTION OF THE INVENTION

Applicants have found that using a spin-on siloxane based BARC (Si-BARC) that forms an absorption gradient by controlled desorption of a dye from the Si-BARC.

A method is provided comprising (a) coating a substrate with an antireflective coating composition comprising a transparent siloxane, a light absorbing dye, and optionally, a curing agent; (b) heating the coated substrate at a temperature where a portion of the dye sublimes out of the antireflective coating composition to form a non-uniform absorption graded antireflective coating layer having a top surface and a bottom surface interfacing with the substrate, where the non-uniform absorption graded antireflective coating layer has an absorption coefficient (k) value of 0.0<k<0.1 at the top surface which increases smoothly and continuously to a value of 0.2>k>1 at the interface of the bottom surface and substrate. The transparent siloxane comprises a repeating unit having the formula

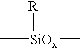

where R is unsubstituted or substituted alkyl, unsubstituted or substituted acyl, unsubstituted or substituted acyloxy, halogen, or hydroxyl; and x is 1.5.

In addition, a non-uniform absorption graded antireflective coating layer having a top surface and a bottom surface interfacing a substrate, where the non-uniform absorption graded antireflective coating layer has an absorption coefficient (k) value of 0.0<k<0.1 at the top surface which increases smoothly and continuously to a value of 0.2>k>1 at the interface of the bottom surface and substrate is also provided.

In addition, a coated substrate comprising a substrate having thereon a non-uniform absorption graded antireflective coating layer formed from an antireflective coating composition and a coating layer of a photoresist over the non-uniform absorption graded antireflective coating layer, where the antireflective coating composition comprises a transparent siloxane and a light absorbing dye is also provided. In some instances, the substrate can be an organic antireflective coating layer, formed from an organic antireflective coating composition.

In addition, a coated substrate comprising a substrate having thereon an antireflective coating layer, formed from an organic antireflective coating composition, the antireflective coating layer having thereon a non-uniform absorption graded antireflective coating layer, formed by the method described herein from a transparent siloxane and a light absorbing dye, the non-uniform absorption graded antireflective coating layer having thereon a coating layer of a photoresist is also provided.

The transparent siloxane is generally a siloxane which does not contain a chromophore moiety (such as, for example, phenyl, naphthyl, and anthryl rings) useful in the present invention comprises a repeating unit having the formula

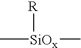

where R is unsubstituted or substituted alkyl, unsubstituted or substituted acyl, unsubstituted or substituted acyloxy, halogen, or hydroxyl; and x is 1.5.

The polymers of this invention are polymerized to give a polymer with a weight average molecular weight from about 1,000 to about 500,000, preferably from about 2,000 to about 50,000, more preferably from about 3,000 to about 30,000.

The siloxane polymer has a silicon content of greater than 15 weight %, preferable greater than 20 weight %, and more preferably greater than 30 weight %.

The novel siloxane polymer may be synthesized as known in the art. Typically the siloxane polymer is made by reacting a compound containing the silicon unit(s) or silane(s), and water in the presence of a hydrolysis catalyst to form the siloxane polymer. The ratio of the various types of substituted and unsubstituted silanes used to form the novel siloxane polymer is varied to provide a polymer with the desirable structure and properties. The silane compound containing the chromophoric unit can be used to add a uniform absorption component to the film; the silane compound containing the crosslinking unit can vary from about 5 mole % to about 90 mole %, preferably from about 10 mole % to about 90 mole %. The crosslinking unit can be considered as an uncondensed site of the monomers from the resins synthesis. The hydrolysis catalyst can be a base or an acid, exemplified by mineral acid, organic carboxylic acid, organic quaternary ammonium base. Further examples of specific catalysts are acetic acid, propionic acid, phosphoric acid, or tetramethylammonium hydroxide. The reaction may be heated at a suitable temperature for a suitable length of time till the reaction is complete. Reaction temperatures can range from about 25° C. to about 170° C. The reaction times can range from about 10 minutes to about 24 hours. Additional organic solvents may be added to solubilize the silane in water, such solvents which are water miscible solvents (e.g. tetrahydrofuran and propyleneglycol monomethylether acetate (PGMEA)) and lower (C₁-C₅) alcohols, further exemplified by ethanol, isopropanol, 2-ethoxyethanol, and 1-methoxy-2-propanol. The organic solvent can range from 5 weight % to about 90 weight %. Other methods of forming the siloxane polymer may also be used, for example suspension in aqueous solution or emulsion in aqueous solution.

The siloxanes contain self-crosslinking functionality in the monomers. The siloxanes may contain other groups such as unsubstituted or substituted alkyl, unsubstituted or substituted acyl, unsubstituted or substituted acyloxy, halogen, or hydroxyl. The acyl or acyloxy groups do not contain chromophore moieties. The acyl group is aliphatic having a total of 2 to 15 carbon atoms, and is, for example, acetyl. Likewise for an acyloxy group, for example, acetoxy.

Silicon-containing antireflective coating materials are typically synthesized from a variety of silane reactants including, for example:

(a) dimethoxysilane, diethoxysilane, dipropoxysilane, methoxyethoxysilane, methoxypropoxysilane, ethoxypropoxysilane, methyl dimethoxysilane, methyl methoxyethoxysilane, methyl diethoxysilane, methyl methoxypropoxysilane, ethyl dipropoxysilane, ethyl methoxypropoxysilane, propyl dimethoxysilane, propyl methoxyethoxysilane, propyl ethoxypropoxysilane, propyl diethoxysilane, butyl dimethoxysilane, butyl methoxyethoxysilane, butyl diethoxysilane, butyl ethoxypropoxysilane, butyl dipropoxysilane, dimethyl dimethoxysilane, dimethyl methoxyethoxysilane, dimethyl diethoxysilane, dimethyl ethoxypropoxysilane, dimethyl dipropoxysilane, diethyl dimethoxysilane, diethyl methoxypropoxysilane, diethyl diethoxysilane, diethyl ethoxypropoxysilane, dipropyl dimethoxysilane, dipropyl diethoxysilane, dibutyl dimethoxysilane, dibutyl diethoxysilane, dibutyl dipropoxysilane, methyl ethyl dimethoxysilane, methyl ethyl diethoxysilane, methyl ethyl dipropoxysilane, methyl propyl dimethoxysilane, methyl propyl diethoxysilane, methyl butyl dimethoxysilane, methyl butyl diethoxysilane, methyl butyl dipropoxysilane, methyl ethyl ethoxypropoxysilane, ethyl propyl dimethoxysilane, ethyl propyl methoxyethoxysilane, dipropyl dimethoxysilane, dipropyl methoxyethoxysilane, propyl butyl dimethoxysilane, propyl butyl diethoxysilane, dibutyl methoxyethoxysilane, dibutyl methoxypropoxysilane, dibutyl ethoxypropoxysilane, trimethoxysilane, triethoxysilane, tripropoxysilane, dimethoxymonoethoxysilane, diethoxymonomethoxysilane, dipropoxymonomethoxysilane, dipropoxymonoethoxysilane, methoxyethoxypropoxysilane, monopropoxydimethoxysilane, monopropoxydiethoxysilane, monobutoxydimethoxysilane, methyl trimethoxysilane, methyl triethoxysilane, methyl tripropoxysilane, ethyl trimethoxysilane, ethyl tripropoxysilane, propyl trimethoxysilane, propyl triethoxysilane, butyl trimethoxysilane, butyl triethoxysilane, butyl tripropoxysilane, methyl monomethoxydiethoxysilane, ethyl monomethoxydiethoxysilane, propyl monomethoxydiethoxysilane, butyl monomethoxydiethoxysilane, methyl monomethoxydipropoxysilane, ethyl monomethoxydipropoxysilane, propyl monomethoxydipropoxysilane, butyl monomethoxy dipropoxysilane, methyl methoxyethoxypropoxysilane, propyl methoxyethoxy propoxysilane, butyl methoxyethoxypropoxysilane, methyl monomethoxymonoethoxybutoxysilane, ethyl monomethoxymonoethoxy monobutoxysilane, propyl monomethoxymonoethoxy monobutoxysilane, butyl monomethoxymonoethoxy monobutoxysilane, tetramethoxysilane, tetraethoxysilane, tetrapropoxysilane, tetrabutoxysilane, trimethoxymonoethoxysilane, dimethoxydiethoxysilane, triethoxymonomethoxysilane, trimethoxymonopropoxysilane, monomethoxytributoxysilane, dimethoxydipropoxysilane, tripropoxymonomethoxysilane, trimethoxymonobutoxysilane, dimethoxydibutoxysilane, triethoxymonopropoxysilane, diethoxydipropoxysilane, tributoxymonopropoxysilane, dimethoxymonoethoxy monobutoxysilane, diethoxymonomethoxy monobutoxysilane, diethoxymonopropoxymonobutoxysilane, dipropoxymonomethoxy monoethoxysilane, dipropoxymonomethoxy monobutoxysilane, dipropoxymonoethoxymonobutoxysilane, dibutoxymonomethoxy monoethoxysilane, dibutoxymonoethoxy monopropoxysilane and monomethoxymonoethoxymonopropoxy monobutoxysilane, and oligomers thereof.

(b) halosilanes, including chlorosilanes, such as trichlorosilane, methyltrichlorosilane, ethyltrichlorosilane, tetrachlorosilane, dichlorosilane, methyldichlorosilane, dimethyldichlorosilane, chlorotriethoxysilane, chlorotrimethoxysilane, chloromethyltriethoxysilane, chloroethyltriethoxysilane, chloromethyltrimethoxysilane, and chloroethyltrimethoxysilane, are also used as silane reactants.

The light absorbing dye is generally a dye that absorbs at the wavelength of interest and which can desorb from the antireflective coating composition when heated such that some but not all of the light absorbing dye desorbs. While not wishing to be bound by theory it is believed that there is a gradient of dye, the dye being more present at the interface between substrate and bottom surface of the antireflective coating layer, formed from the antireflective coating composition, and the amount of dye diminishing as you pass through the antireflective coating layer to the top surface thereof, providing a non-uniform absorption graded antireflective coating layer which has an absorption coefficient (k) value of 0.0<k<0.1 at the top surface which increases smoothly and continuously to a value of 0.2>k>1 at the interface of the bottom surface and substrate.

Examples of dyes include

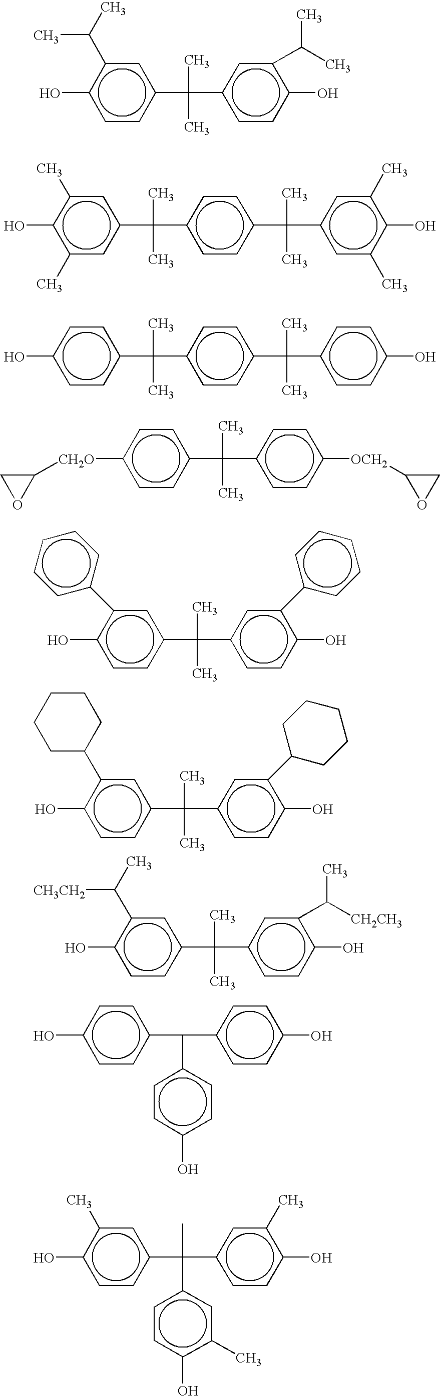

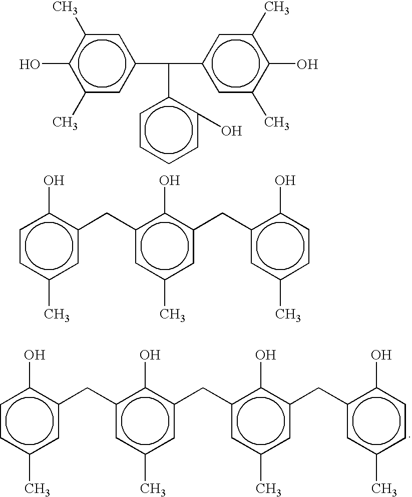

The composition can optionally contain curing agent. The curing agent can be an acid generator, such as a thermal acid generator capable of generating a strong acid upon heating. The thermal acid generator (TAG) may be any one or more that upon heating generates an acid which can propagate crosslinking of the polymer. When present in the composition, preferably, the thermal acid generator is activated at above 90° C. and more preferably at above 120° C., and even more preferably at above 150° C. Examples of thermal acid generators include iodonium and sulfonium salts, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid. The curing agent can also be a compound having the formula Z⁺A⁻, where Z is a cation selected from tetraalkylammonium, tetraalkylphosphonium, trialkylmonoarylammonium, trialkylmonoarylphosphonium, dialkyldiarylammonium, dialkyldiarylphosphonium, monoalkyltriarylammonium, monoalkyltriarylphosphonium, tetraarylammonium, tetraarylphosphonium, unsubstituted or substituted iodonium, and unsubstituted or substituted sulfonium and A is an anion containing a group selected from halide, hypohalite, halite, halate, perhalate, hydroxide, monocarboxylate, dicarboxylate, carbonate, bicarbonate, silanolate, alkoxide, aryloxide, nitrate, azide, peroxymonosulfate, peroxydisulfate, phosphate, dihydrogen phosphate, sulfate, bisulfate, sulfonate, and guanidine, as well as the hydrates thereof, and mixtures thereof. In addition, the curing agent can also be a sulfuric acid generator which decomposes at a temperature less than or equal to about 500° C. can include sulfuric acid, hydrogen sulfate or sulfate salts of trialkylamine, unsubstituted or substituted 25 dialkylmonocyloalkylamine, unsubstituted or substituted monoalkyldicycloalkylamine, unsubstituted or substituted tricycloalkylamine, triarylamine, unsubstituted or substituted diarylmonoalkylamine, unsubstituted or substituted monoaryldialkylamine, unsubstituted or substituted triarylamine, unsubstituted or substituted aziridine, unsubstituted or substituted azetidine, unsubstituted or substituted pyrrol, unsubstituted or substituted pyridine, unsubstituted or substituted piperidine, or unsubstituted or substituted piperazine, such as triethylamine hydrogen sulfate, tributylamine hydrogen sulfate, piperazine sulfate, and the like.

In addition, the curing agent can also be a halide source. The halide source can be just about any material which provides a halide anion to react with the polymer. Depending upon the application of the composition of the present invention, it may be more advantageous to use certain halide sources over other halide sources. Examples of halide sources include aliphatic quaternary ammonium salts (e.g., a tetraC₁₋₆ alkylammonium halide such as tetramethylammonium chloride, tetraethylammonium chloride, tetramethylammonium bromide and tetraethylammonium bromide, a triC₁₋₆ alkylC₈₋₂₀ alkylammonium halide such as trimethyllaurylammonium chloride and trimethyllaurylammonium bromide, a diC₁₋₆ alkyldiC₈₋₂₀ alkylammonium halide such as dimethyldilaurylammonium chloride and dimethyldilaurylammonium bromide), especially a tetraC₁₋₄ alkylammonium halide (e.g., a tetraC₁₋₂ alkylammonium halide), a triC₁₋₄ alkylC₁₀₋₁₆ alkylammonium halide (e.g., a triC₁₋₂ alkylC₁₀₋₁₄ alkylammonium halide), a diC₁₋₄ alkyldiC₁₀₋₁₆ alkylammonium halide (e.g., a diC₁₋₂ alkyldiC₁₀₋₁₄ alkylammonium halide), aliphatic/aryl quaternary ammonium salts (e.g., benzyltriC₁₋₁₆ alkyl ammonium halide). Examples of these salts include tetrabutylammonium chloride, benzyltrimethylammonium chloride, tetraethylammonium chloride, benzyltributylammonium chloride, cetyltrimethylammonium chloride, methyltrioctylammonium chloride, tetrabutylammonium chloride, benzyltrimethylammonium chloride, as well as the corresponding fluorides, bromides, and iodides.

Other examples of suitable halide sources are diquaternary ammonium dihalide salts such as compounds having the general formula

[(R′)₃N⁺(Z)ₘN⁺(R′)₃](X⁻)₂

wherein each R′ is individually alkyl of from 1 to 20 carbon atoms, heteroalkyl of from 1 to 20 carbon atoms, aryl, heteroaryl, cycloalkyl of from 3 to 6 carbon atoms, cycloheteroalkyl of from 3 to 6 carbon atoms, or combinations thereof; N is the quadricoordinate element nitrogen, or the heteroatom nitrogen in an alicyclic, heteroalicyclic or heteroaromatic structure X is an anion; Z is a bridging member selected from the group consisting of alkyl of from 1 to 20 carbon atoms, alkenyl of from 2 to 20 carbon atoms, aryl, heteroalkyl of from 1 to 20 carbon atoms, heteroalkenyl of from 2 to 20 carbon atoms and heteroaryl; and m is 1 to 10. Examples of these compounds include [(CH₃)₃N⁺(CH₂)₆N⁺(CH₃)₃](Cl⁻)₂, [(C₃H₇)₃N⁺(CH₂)₆N⁺(C₃H₇)₃](Cl⁻)₂, [(CH₃)₃N⁺(C₂H₄)₆N⁺(CH₃)₃](Br⁻)₂, [(C₆H₅)₃N⁺(CH₂)₆N⁺(CH₃)₃](Cl⁻)₂, [(C₆H₅)₃N⁺(C₂H₄)₂N⁺(CH₃)₃](Cl⁻)₂, and the like, etc. Another example of a diquaternary ammonium halide salt is N,N′-difluoro-2,2′-bipyridinium(bistetrafluoroborate) (known as MEC-31). Yet another example is tetrakis(dimethylamino)ethene (TDAE)/CF3 complex.

Other examples of halide sources include tetraalkylammonium dihalotriaryl(or trialkyl or mixtures of aryl and alkyl)disilicate which have the general formula

[aryl]_{q}[alklyl]ᵣSi[F]ₛ

where q is 1 or 2, r is 1 or 2, and s is 2 or 3.

One example is a compound having the formula

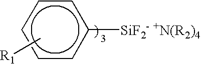

where R₁ is zero to three substituents, each of which are independently alkyl, alkenyl, aryl alkanoyl, alkoxy, or nitro; and R₂ is an alkyl group, an example being tetrabutylammonium difluorotriphenylsilicate.

Other examples are compounds having the formulae

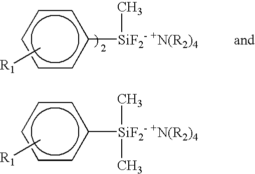

where R₁ and R₂ are defined above.

These types of salts are more fully described in U.S. Pat. Nos. 6,414,173 and 6,203,721, both of which are incorporated herein by reference.

Additional diquaternary ammonium halide salts are also diquaternary ammonium salts of DABCO (1,4-diazabicyclo[2.2.2]octane), shown by the formula

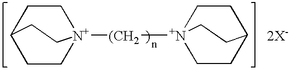

where n is 1 to 10 and X is a halide. These salts are more fully described in U.S. Pat. No. 4,559,213, which is incorporated herein by reference.

Other halide sources include alkali metal salts (e.g., LiCl, NaCl, KCl, KBr, etc), alkaline earth metal salts (e.g., CaCl₂, MgCl₂, etc), pyridinium salts such as benzyl-3-hydroxypyridinium chloride, imidazolidine salts such as 1,3-didecyl-2-methylimidazolium chloride, tetrazolium salts such as 2,3,5-triphenyl-tetrazolium chloride, and the like, etc. Yet other halide sources include halogenated organic compounds that can release halide by an elimination reaction under heat.

In many instances, the nitrogen atom in the above salts can be replaced with a Group VA element such as phosphorus, antimony, and arsenic, such as tetrabutylphosphonium chloride, tetramethylphosphonium chloride, tetraphenylphosphonium chloride, and the like.

Other halide sources include materials such as 1-fluoro-4-chloromethyl-1,4-diazoniabicyclo[2.2.2] octane bis(tetrafluoroborate) (tradename Selectfluor), 1-fluoro-4-hydroxy-1,4-diazoniabicyclo[2.2.2]octane bis(tetrafluoroborate) (tradename Accufluor), N,N′-difluoro-2,2′-bipyridinium bis(tetrafluoroborate), the ‘N-F’ reagents (e.g., R₂N—F), the ‘[N—F]⁺ reagents (e.g., R₃N⁺—F), 2,2-difluoro-1,3-dimethylimidazolidine, diethylaminosulfur trifluoride, RₐR_{b}N—CF₂—R_{c}, where Rₐ is hydrogen or alkyl and R_{b} and R_{c} are each selected from alkyl or aryl (tradename Fluorinox), perfluorobutanesulfonyl fluoride, and the like, etc.

The antireflection coating composition of the present invention contains 1 weight % to about 15 weight % of the siloxane polymer, and preferably 4 weight % to about 10 weight % of total solids. The curing agent, when used in the composition, may be incorporated in a range from about 0.1 to about 20 weight % by total solids of the siloxane polymer.

The solid components of the antireflection coating composition are mixed with a solvent or mixtures of solvents that dissolve the solid components of the antireflective coating. Suitable solvents for the antireflective coating composition may include, for example, a glycol ether derivative such as ethyl cellosolve, methyl cellosolve, propylene glycol monomethyl ether, diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate; carboxylates such as ethyl acetate, n-butyl acetate and amyl acetate; carboxylates of di-basic acids such as diethyloxylate and diethylmalonate; dicarboxylates of glycols such as ethylene glycol diacetate and propylene glycol diacetate; and hydroxy carboxylates such as methyl lactate, ethyl lactate, ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; lactones such as butyrolactone; an amide derivative such as dimethylacetamide or dimethylformamide, anisole, and mixtures thereof.

Other components may be added to enhance the performance of the coating, e.g. lower alcohols, crosslinking agents, surface leveling agents, adhesion promoters, antifoaming agents, etc.

Since the antireflective film is coated on top of the substrate and is further subjected to dry etching, it is envisioned that the film is of sufficiently low metal ion level and of sufficient purity that the properties of the semiconductor device are not adversely affected. Treatments such as passing a solution of the polymer through an ion exchange column, filtration, and extraction processes can be used to reduce the concentration of metal ions and to reduce particles.

The antireflective coating composition is coated on the substrate using techniques well known to those skilled in the art, such as dipping, spin coating or spraying. The film thickness of the antireflective coating ranges from about 15 nm to about 100 nm. The coating is further heated on a hot plate or convection oven for a sufficient length of time to remove any residual solvent and induce crosslinking, and thus insolubilizing the antireflective coating to prevent intermixing between the antireflective coatings. The preferred range of temperature is from about 90° C. to about 300° C. If the temperature is below 90° C. then insufficient loss of solvent or insufficient amount of crosslinking takes place, and at temperatures above 300° C. the composition may become chemically unstable. A film of photoresist is then coated on top of the uppermost antireflective coating and baked to substantially remove the photoresist solvent. An edge bead remover may be applied after the coating steps to clean the edges of the substrate using processes well known in the art.

The substrates over which the antireflective coatings are formed can be any of those typically used in the semiconductor industry. Suitable substrates include, without limitation, silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/V compounds, as well as the foregoing substrates coated with spin-on carbon rich layers or amorphous carbon layers. The substrate may comprise any number of layers made from the materials described above. In some instances, the compositions of the present application will be coated over the spin-on carbon rich layer or the amorphous carbon layer.

Photoresists can be any of the types used in the semiconductor industry, provided the photoactive compound in the photoresist and the antireflective coating absorb at the exposure wavelength used for the imaging process.

To date, there are several major deep ultraviolet (uv) exposure technologies that have provided significant advancement in miniaturization, and these radiation of 248 nm, 193 nm, 157 and 13.5 nm. Photoresists for 248 nm have typically been based on substituted polyhydroxystyrene and its copolymers/onium salts, such as those described in U.S. Pat. No. 4,491,628 and U.S. Pat. No. 5,350,660. On the other hand, photoresists for exposure below 200 nm require non-aromatic polymers since aromatics are opaque at this wavelength. U.S. Pat. No. 5,843,624 and U.S. Pat. No. 6,866,984 disclose photoresists useful for 193 nm exposure. Generally, polymers containing alicyclic hydrocarbons are used for photoresists for exposure below 200 nm. Alicyclic hydrocarbons are incorporated into the polymer for many reasons, primarily since they have relatively high carbon to hydrogen ratios which improve etch resistance, they also provide transparency at low wavelengths and they have relatively high glass transition temperatures. U.S. Pat. No. 5,843,624 discloses polymers for photoresist that are obtained by free radical polymerization of maleic anhydride and unsaturated cyclic monomers. Any of the known types of 193 nm photoresists may be used, such as those described in U.S. Pat. No. 6,447,980 and U.S. Pat. No. 6,723,488, and incorporated herein by reference.

Two basic classes of photoresists sensitive at 157 nm, and based on fluorinated polymers with pendant fluoroalcohol groups, are known to be substantially transparent at that wavelength. One class of 157 nm fluoroalcohol photoresists is derived from polymers containing groups such as fluorinated-norbornenes, and are homopolymerized or copolymerized with other transparent monomers such as tetrafluoroethylene (U.S. Pat. No. 6,790,587, and U.S. Pat. No. 6,849,377) using either metal catalyzed or radical polymerization. Generally, these materials give higher absorbencies but have good plasma etch resistance due to their high alicyclic content. More recently, a class of 157 nm fluoroalcohol polymers was described in which the polymer backbone is derived from the cyclopolymerization of an asymmetrical diene such as 1,1,2,3,3-pentafluoro-4-trifluoromethyl-4-hydroxy-1,6-heptadiene (Shun-ichi Kodama et al Advances in Resist Technology and Processing XIX, Proceedings of SPIE Vol. 4690 p 76 2002; U.S. Pat. No. 6,818,258) or copolymerization of a fluorodiene with an olefin (WO 01/98834-A1). These materials give acceptable absorbance at 157 nm, but due to their lower alicyclic content as compared to the fluoro-norbornene polymer, have lower plasma etch resistance. These two classes of polymers can often be blended to provide a balance between the high etch resistance of the first polymer type and the high transparency at 157 nm of the second polymer type. Photoresists that absorb extreme ultraviolet radiation (EUV) of 13.5 nm are also useful and are known in the art.

After the coating process, the photoresist is imagewise exposed. The exposure may be done using typical exposure equipment. The exposed photoresist is then developed in an aqueous developer to remove the treated photoresist. The developer is preferably an aqueous alkaline solution comprising, for example, tetramethyl ammonium hydroxide. The developer may further comprise surfactant(s). An optional heating step can be incorporated into the process prior to development and after exposure.

The process of coating and imaging photoresists is well known to those skilled in the art and is optimized for the specific type of resist used.

The gradient Si-BARC of the present application can also act as a hard mask in a trilayer stack. For trilayer processing applications, photoresist thicknesses can be much thinner (50-200 nm) than for single layer processing applications, resulting in low aspect ratio lines. The trilayer bottom antireflective coating instead is typically 100-700 nm thick, and the middle layer, formed from the method described herein, is typically 20-150 nm thick. A generalized process for forming a trilayer stack on the substrate is first by the application of an organic antireflective coating, followed by an inorganic coating (the non-uniform absorption graded antireflective coating layer herein; also called a hard mask), followed by a resist. The resist is patterned with advanced lithographic techniques. The pattern is then transferred into the underlying layers by opening the hardmask with a highly selective etch process. The organic antireflective layer (carbon underlayer) under the hardmask is then opened using an oxygen-rich plasma etch, which takes advantage of the large selectivity achievable between inorganic silicon-type materials and organics in an oxygen plasma. The substrate is then patterned with the relief image now present in the carbon layer. Organic antireflective coatings are well known to those skilled in the art. Examples of organic antireflective coatings are found in U.S. Pat. No. 6,803,168 and U.S. Pat. No. 6,329,117, the contents of both are hereby incorporated herein by reference.

The patterned substrate can then be dry etched with an etching gas or mixture of gases, in a suitable etch chamber to remove the exposed portions of the antireflective film, with the remaining photoresist acting as an etch mask. Various etching gases are known in the art for etching antireflective coatings, such as those comprising CF₄, CF₄/O₂, CF₄/CHF₃, or Cl₂/O₂.

Amplification of etch depths is achieved through two successive reactive ion etch steps in which an image in a thin organic photoresist of low etch resistance is replicated, at a higher aspect ratio, in a higher etch resistant carbon underlayer. This transformation is made possible by placing an elementally dissimilar layer in-between the resist and underlayer and in this case it is a graded Si-BARC. This layer has distinct difference in etch response to the organic layers that border it. In addition, these additional two layers beneath the photoresist (Si-BARC and organic antireflective layer (carbon underlayer)) provide superior anti-reflection control.

Each of the documents referred to above are incorporated herein by reference in its entirety, for all purposes. The following specific examples will provide detailed illustrations of the methods of producing and utilizing compositions of the present invention. These examples are not intended, however, to limit or restrict the scope of the invention in any way and should not be construed as providing conditions, parameters or values which must be utilized exclusively in order to practice the present invention.

### EXAMPLES

50 g of acetoxyethylsilsesquioxane (Gelest SST BAE1.2), 2.0 g triphenol ethane and 0.2 g of dodecylbenzenesulfonic acid triethylamine were mixed in a suitable container. The resulting mixture was then filtered through 0.2 μm PTFE filter. A diluted formulation was prepared by taking 10 g of the above and diluting with 90 g of propylene glycol monomethyl ether (PGME). Silicon wafers were coated with the mixture at 2000 rpm on a Laurell WS-400B-6NPP/lite spin coater. The coated wafers were then baked at the temperatures shown in Table 1 (thicker version corresponds to (1) and thinner version corresponds to (2)) and ellispometic data were recorded on a J. A. Woollam WVASE VU-32 Ellipsometer Modeling of the film thickness and optical indices was achieved in two ways. First, the coated materials were treated as a composition-uniform film. To determine the film thickness we first apply a Cauchy model over a transparent region of the measured spectrum which falls in-between 600 and 1000 nm. A normal fit is performed to determine the An, Bn, and Cn Cauchy parameters and the film thickness. Optical constants were fitted at each wavelength with the layer thicknesses held fixed using a point-by-point fit. The resulting film thickness (FT) and optical properties are shown in Table 1 under Bulk Optical Properties.

The second modeling of the film is performed using an effective medium approximation (EMA). WVASE software supports EMA modeling of films that exhibit non-uniform optical properties along the direction of the film normal. The EMA model blends two materials with discrete optical properties to model a graded film. The procedure requires two materials layers that can exemplify the composition of the top and bottom of the graded film. We used the siloxane film without dye to represent the top of the graded layer. The bottom is represented by fitting a GENOSC™ (generalized oscillator model, available in the WVASE32 library) model to the point-by-point model above. Absorptions in the GENOSC™ model are increased so that the k value at 193 nm is equal to 1. This allows for an easier determination of the k values from compositional ratios making k equal to the compositions percentage of the lower absorbing layer. In our EMA model we assume that the composition trends in the film normal change linearly. The GENOSC™ model is further described in the WVASE32® Manual, the contents of which are hereby incorporated herein by reference. In addition, the GENOSC™ model is further described in United States Published Patent Application No. 20040257567 (Ser. No. 10/849740), the contents of which are hereby incorporated herein by reference.

| | | | | | Linear Graded | |
|---|---|---|---|---|---|---|
| | | | | | Optical | |
| | Bulk Optical Properties | | | | Properties* | |
| | Bake | FT | n | k @ | k @ | k @ |
| Example | (° C.) | (nm) | @ 193 nm | 193 nm | Bottom | Top |
| (1) | 300 | 847 | 1.61 | 0.11 | 0.33 | 0.08 |
| (1) | 250 | 1398 | 1.59 | 0.2 | 0.57 | 0.37 |
| (2) | 300 | 51 | 1.61 | 0.012 | 0.05 | <0 |
| (2) | 250 | 54 | 1.63 | 0.055 | 0.17 | 0.001 |
| (2) | 200 | 62 | 1.63 | 0.17 | 0.60 | 0.46 |

*k is proportional to the composition % of the bottom material

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

1. A method comprising:
(a) coating a substrate with an antireflective coating composition comprising a transparent siloxane, a light absorbing dye, and optionally, a curing agent;
(b) heating the coated substrate at a temperature where a portion of the dye sublimes out of the antireflective coating composition to form a non-uniform absorption graded antireflective coating layer having a top surface and a bottom surface interfacing with the substrate, where the non-uniform absorption graded antireflective coating layer has an absorption coefficient (k) value of 0.0<k<0.1 at the top surface which increases smoothly and continuously to a value of 0.2>k>1 at the interface of the bottom surface and substrate.

2. The method of claim 1 wherein the transparent siloxane comprises a repeating unit having the formula 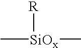
where R is unsubstituted or substituted alkyl, unsubstituted or substituted acyl, unsubstituted or substituted acyloxy, halogen, or hydroxyl; and x is 1.5.

3. The method of claim 1 wherein the light absorbing dye is selected from 2,6-bis(2-hydroxy-5-methylbenzyl)-4-methylphenol, 2,2′-methylenebis[6-(2-hydroxy-5-methylbenzyl)-p-cresol], 4,4′,4″-methylidynetriphenol, tri(3-methyl-4-hydroxyphenyl)methane, 4,4′-(2-hydroxybenzylidene)bis(2,3,6-trimethylphenol), 2,2-bis(2-hydroxy-5-biphenylyl)propane, 2,2-bis(3-cyclohexyl-4-hydroxyphenyl)propane, 2,2-bis(3-sec-butyl-4-hydroxyphenyl)propane, 2,2-bis(4-hydroxyphenyl)propane diglycidyl ether, α,α′-bis(4-hydroxy-3,5-dimethylphenyl)-1,4-diisopropylbenzene, α,α′-bis(4-hydroxyphenyl)-1,4-diisopropylbenzene, 2,2-bis(4-hydroxy-3-isopropylphenyl)propane, and mixtures thereof.

4. The method of claim 1 wherein the coated substrate is heated at a temperature between about 150° C. and about 350° C.

5. The method of claim 1 wherein the non-uniform absorption graded antireflective coating layer is overcoated with a photoresist composition.

6. The method of claim 1 wherein substrate has an organic antireflective coating layer thereon, formed from an organic antireflective coating composition, before being coated with the antireflective coating composition of step (a).

7. The method of claim 5 wherein the photoresist composition forms a photoresist layer having an absorption coefficient (k) of 0.0<k<0.1.

8. A non-uniform absorption graded antireflective coating layer having a top surface and a bottom surface interfacing a substrate, where the non-uniform absorption graded antireflective coating layer has an absorption coefficient (k) value of 0.0<k<0.1 at the top surface which increases smoothly and continuously to a value of 0.2>k>1 at the interface of the bottom surface and substrate.

9. The non-uniform absorption graded antireflective coating layer of claim 8 being formed from an antireflective coating composition comprising a transparent siloxane, a light absorbing dye, and optionally, a curing agent.

10. The non-uniform absorption graded antireflective coating layer of claim 9 wherein the transparent siloxane comprises a repeating unit having the formula 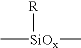
where R is unsubstituted or substituted alkyl, unsubstituted or substituted acyl, unsubstituted or substituted acyloxy, halogen, or hydroxyl; and x is 1.5.

11. The non-uniform absorption graded antireflective coating layer of claim 9 wherein the light absorbing dye is selected from 2,6-bis(2-hydroxy-5-methylbenzyl)-4-methylphenol, 2,2′-methylenebis[6-(2-hydroxy-5-methylbenzyl)-p-cresol], 4,4′,4″-methylidynetriphenol, tri(3-methyl-4-hydroxyphenyl)methane, 4,4′-(2-hydroxybenzylidene)bis(2,3,6-trimethylphenol), 2,2-bis(2-hydroxy-5-biphenylyl)propane, 2,2-bis(3-cyclohexyl-4-hydroxyphenyl)propane, 2,2-bis(3-sec-butyl-4-hydroxyphenyl)propane, 2,2-bis(4-hydroxyphenyl)propane diglycidyl ether, α,α′-bis(4-hydroxy-3,5-dimethylphenyl)-1,4-diisopropylbenzene, α,α′-bis(4-hydroxyphenyl)-1,4-diisopropylbenzene, 2,2-bis(4-hydroxy-3-isopropylphenyl)propane, and mixtures thereof.

12. The non-uniform absorption graded antireflective coating layer of claim 8 wherein the substrate is an organic antireflective coating layer formed from an organic antireflective coating composition which is coated over a material selected from silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/V compounds.

13. A coated substrate comprising a substrate having thereon a non-uniform absorption graded antireflective coating layer formed from an organic antireflective coating composition and a coating layer of a photoresist over the non-uniform absorption graded antireflective coating layer, where the antireflective coating composition comprises a transparent siloxane, a light absorbing dye, and optionally, a curing agent.

14. The coated substrate of claim 13 wherein the antireflective coating composition comprises a transparent siloxane and a light absorbing dye.

15. The coated substrate of claim 14 wherein the transparent siloxane comprises a repeating unit having the formula 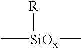
where R is unsubstituted or substituted alkyl, unsubstituted or substituted acyl, unsubstituted or substituted acyloxy, halogen, or hydroxyl; and x is 1.5.

16. The coated substrate of claim 14 wherein the light absorbing dye is selected from 2,6-bis(2-hydroxy-5-methylbenzyl)-4-methylphenol, 2,2′-methylenebis[6-(2-hydroxy-5-methylbenzyl)-p-cresol], 4,4′,4″-methylidynetriphenol, tri(3-methyl-4-hydroxyphenyl)methane, 4,4′-(2-hydroxybenzylidene)bis(2,3,6-trimethylphenol), 2,2-bis(2-hydroxy-5-biphenylyl)propane, 2,2-bis(3-cyclohexyl-4-hydroxyphenyl)propane, 2,2-bis(3-sec-butyl-4-hydroxyphenyl)propane, 2,2-bis(4-hydroxyphenyl)propane diglycidyl ether, α,α′-bis(4-hydroxy-3,5-dimethylphenyl)-1,4-diisopropylbenzene, α,α′-bis(4-hydroxyphenyl)-1,4-diisopropylbenzene, 2,2-bis(4-hydroxy-3-isopropylphenyl)propane, and mixtures thereof.

17. The coated substrate of claim 13 where the non-uniform absorption graded antireflective coating layer has a top surface and a bottom surface interfacing the substrate, the non-uniform absorption graded antireflective coating layer having an absorption coefficient (k) value of 0.0<k<0.1 at the top surface which increases smoothly and continuously to a value of 0.2>k>1 at the interface of the bottom surface and substrate.

18. The coated substrate of claim 13 wherein the substrate is an organic antireflective layer formed from an organic antireflective coating composition which is coated over a material selected from silicon, silicon substrate coated with a metal surface, copper coated silicon wafer, copper, aluminum, polymeric resins, silicon dioxide, metals, doped silicon dioxide, silicon nitride, tantalum, polysilicon, ceramics, aluminum/copper mixtures; gallium arsenide and other such Group III/V compounds.
